(19) United States
(12) Patent Application Publication
(10) Pub. No.: US 2002/0167896 A1
(43) Pub. Date: Nov. 14, 2002

(54) Methods and apparatus for configuration information recovery

(76) Inventor: Arvind Puntambekar, Westford, MA (US)

Correspondence Address: LAHIVE & COCKFIELD, 28 STATE STREET, BOSTON, MA, 02109, US

(21) Appl. No.: 09/854,198

(22) Filed: May 11, 2001

(51) Int. Cl. G01R 31/08; H04L 12/28

(52) U.S. Cl. 370/216; 370/244; 370/400

(57) ABSTRACT

A system and method for protecting and recovering configuration information in a node during a configuration mismatch. The configuration mismatch may involve the insertion of a foreign switch management card into a node chassis. The configuration mismatch may alternatively involve a discrepancy between a hardware configuration of the node and the software configuration of the node. A mismatched node notifies a user of the mismatch and prevents mismatched configuration information from being downloaded to the node. The node utilizes default configuration information to maintain a traffic flow during mismatch while the node undergoes recovery procedures.

### FIELD OF THE INVENTION

The present invention relates to communications networks. More particularly, the present invention relates to the recovery of configuration information in a node of a communications network.

### BACKGROUND OF THE INVENTION

An optical communications network is typically comprised of a plurality of nodes connected by an optical communications medium. Data is modulated onto light waves and transmitted though the network by means of the optical communications medium. In a communications network, a node is a processing location where transmitting or receiving equipment is connected to the network. Nodes are distributed across a communications network for performing switching, routing, multiplexing/demultiplexing and other network functions. The nodes can be configured as a number of different network topologies, such as line, a ring, a mesh, star and/or other suitable topology.

When a node runs with improper and/or invalid configuration information, a network meltdown can ensue. The configuration for a node generally includes information regarding the number and location of ports, trunks, cross-connects, tunnels and other hardware elements in the node, as well as the IP address for the node. An IP address is an identifier for a node on a TCP/IP network. Networks utilizing TCP/IP protocol route messages based on the IP address of the destination. The format of an IP address is typically a 32-bit numeric address written as four numbers separated by periods. A port comprises an interface of the node, where information signals enter or exit the node. A port may be a trunk port connecting the node with another node, or a line port connecting the node and the network to a user. A trunk comprises a communications channel between two nodes, through which information is transmitted between nodes. A cross-connect comprises a network switching element within the node for switching an information signal from an ingress port to an egress port. Tunnels refer to the channels that enable one network to send data via another network's connections. Tunneling works by encapsulating a network protocol within packets carried by the network. A node's configuration further includes information regarding the arrangement of the ports, trunks and cross-connects, whether each port is an ingress or an egress port, a trunk port or a line port, which ports are cross-connected with each other, the state of each port, trunk identifiers and other information related to the node's configuration. Failures of configuration mismatch can be disruptive and damaging to a system if not handled correctly.

### SUMMARY OF THE INVENTION

The present invention provides a system and method for protecting and recovering configuration information in a node under several conditions. The present invention protects a network from invalid configuration information in a node. The present invention detects mismatched configurations and preserves existing configuration information in a node in the case of a mismatch between the hardware configuration of a node and configuration information stored in the software of the node. The present invention further prevents disruption of the flow of information signals through a node during a mismatch by utilizing a default configuration file to maintain traffic flow.

According to one embodiment of the invention, the present invention performs a consistency check to detect a foreign switch management card or other control card residing in a node chassis. The node detects a foreign card by comparing a chassis identification code stored in the backplane of the node with a chassis identification code programmed in a configuration file in the control plane of the node. When a foreign card is detected, the node of the present invention notifies a user of a mismatch and prevents configuration information stored in the foreign card from being downloaded to the node.

According to an alternate embodiment of the present invention, at least one daemon of the node performs consistency checks between configuration information stored in a configuration file and the hardware configuration of the node. The consistency check raises an alarm if there is a mismatch. The node continues to process and route traffic through the node during a mismatch.

### BRIEF DESCRIPTION OF THE DRAWINGS

FIG. 1 illustrates a communications network suitable for implementing an illustrative embodiment of the present invention

FIG. 2 illustrates a node in a communications network according to an illustrative embodiment of the present invention.

FIG. 3 is a flow chart diagramming a verification process for detecting a foreign SMC in a node according to an illustrative embodiment of the present invention.

FIG. 4 is a flow chart diagramming a consistency check for detecting a configuration mismatch in a node according to an illustrative embodiment of the present invention.

### DETAILED DESCRIPTION

The illustrative embodiment of the present invention provides a system and method for configuration information recovery in a node. The present invention protects a communications network from a catastrophic event due to invalid configurations in a node while avoiding changes in existing hardware configurations and maintaining traffic flow through the node. The illustrative embodiment will be described below relative to an illustrative embodiment in an optical communications network. Nevertheless, those skilled in the art will appreciate that the present invention may also be implemented in other types of communications networks.

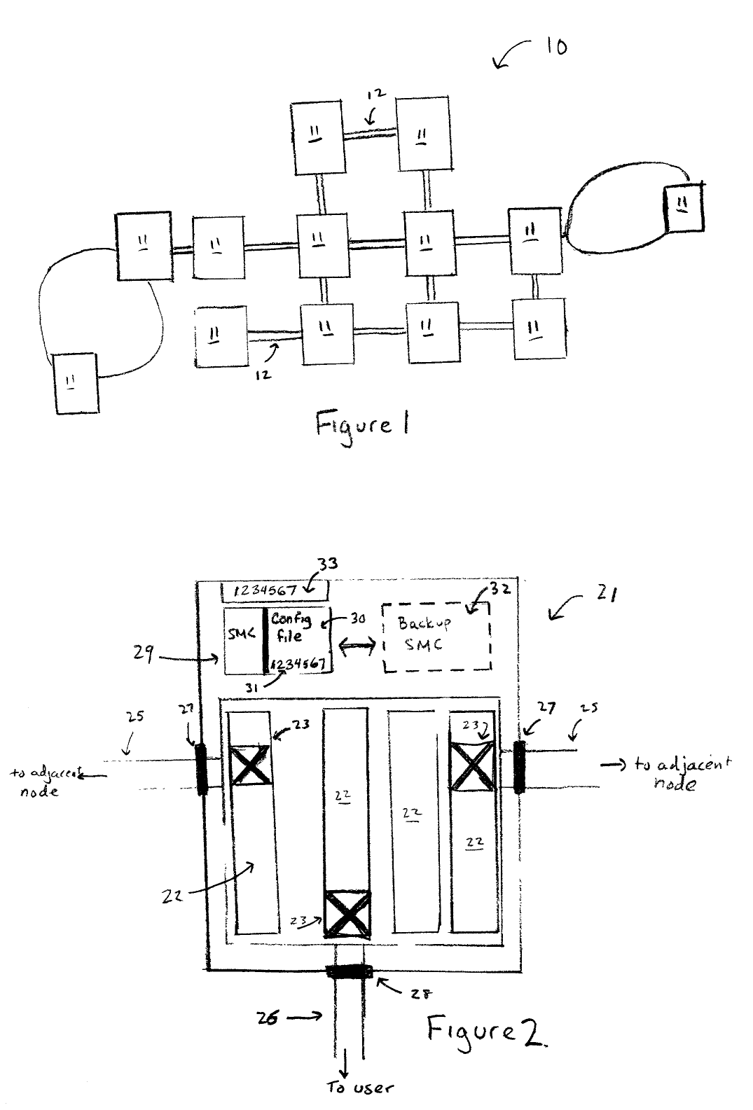

FIG. 1 illustrates a communications network 10 suitable for implementing the illustrative embodiment of the present invention. While the illustrative embodiment is described relative to a network with a mesh-based topology, it is understood that the present invention may be utilized with a number of different network topologies. The network 10 comprises a plurality of nodes 11 interconnected by trunks 12 in the form of fiber optic cables providing a communications channel between the nodes. In a network, a node is a processing location where transmitting or receiving equipment is connected to the network. As illustrated, in a mesh-based topology there are a multitude of possible paths between two nodes.

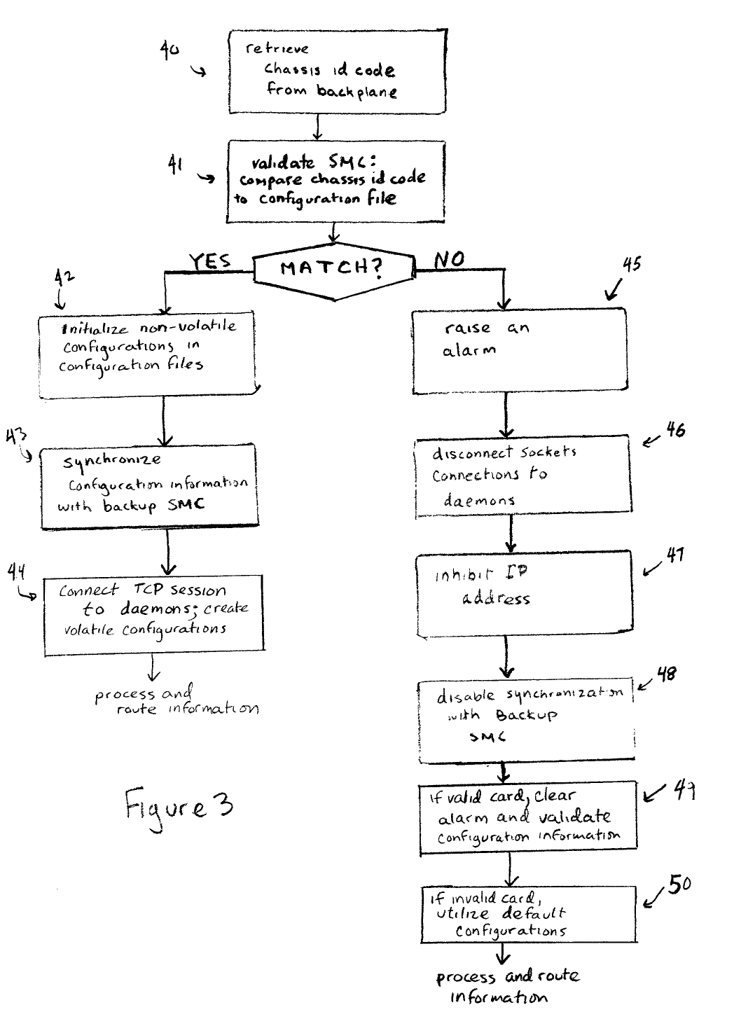

FIG. 2 shows an example of a node of an optical communications network, illustrated as switch 21, according to the illustrative embodiment of the invention. The switch includes one or more line cards 22, including cross-connects 23 and other hardware elements. The line cards 22 provide a physical transmission medium within the node for receiving and transmitting information signals. Each line card 22 receives and switches traffic to an appropriate port through a cross-connect 23 and other signaling software. Trunks 25 interface with the node to provide connections to adjacent nodes in the network, while a line 26 provides a connection to a user of the network. A trunk port 27 provides an interface for a connection to the adjacent node and a line port 28 provides an interface for a connection to the user. A Switch Management Card (SMC) 29 provides the control software for running the node and serves as the “master control” of the node. A hard disk on the SMC stores a configuration file 30 for the node. The configuration file contains configuration information for the node, including information regarding the number, type and location of the ports, trunks, tunnels and cross-connects, as well as the IP address of the node. The configuration file 30 further includes a chassis identification (ID) code 31 identifying a chassis corresponding to the SMC. According to one embodiment, the node of the present invention further comprises a standby or secondary SMC 32 that is synchronized with and redundant to the primary SMC 29. The secondary SMC serves as a backup to the primary SMC. If the primary SMC 29 fails, the standby SMC 32 is configured to automatically assume control of the switch.

According to an illustrative embodiment of the present invention, a chassis ID code 33 is programmed into the backplane of the node during manufacture. The chassis ID code 33 provides a unique identification for the node in the network, and facilitates communication and routing of traffic between the nodes. If a SMC 29 is correctly matched with the appropriate chassis, the chassis ID code 33 stored in the backplane of the node and the chassis ID code 31 stored in the configuration file 30 on the SMC are identical. The network utilizes the chassis ID code for matching a SMC card to a corresponding node. According to an illustrative embodiment, the chassis ID code comprises a unique serial number for each node. The configuration illustrated in FIG. 2 is intended to be merely illustrative and not limiting of the present invention.

A feature of the present invention involves the separation of the hardware plane, i.e. the line cards, from the control plane by running the control software for the node in a separate card, such as the switch management card of the illustrative embodiment. In this manner, the hardware plane is isolated from configuration problems associated with the software or control plane. The node is configured such that the node can continue to pass traffic for a short period of time without the SMC in place.

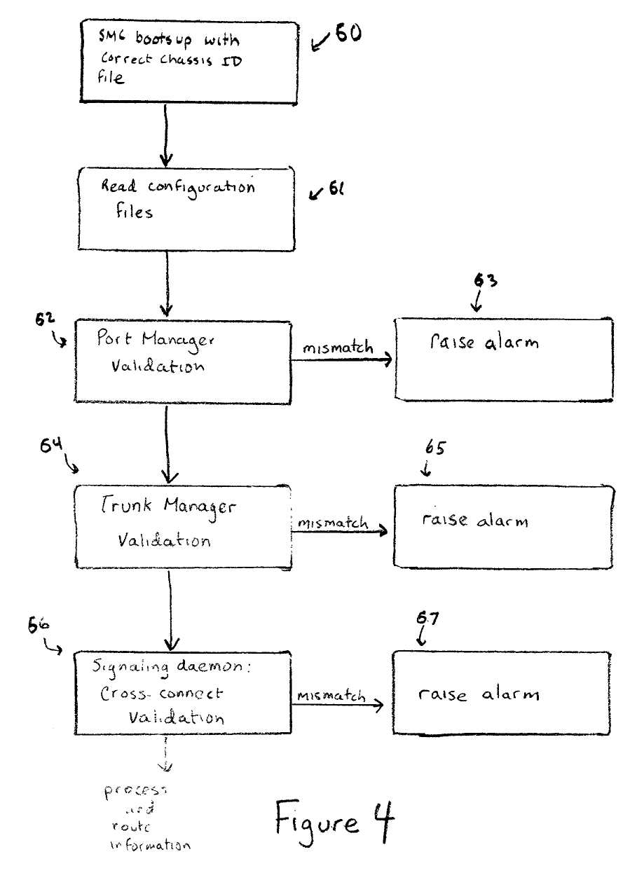

The present invention provides a method of recovering configuration information for a node under a number of failure circumstances. It is important for the SMC to contain correct configuration information for the node. If the configuration information is incorrect or invalid, the SMC cannot properly monitor and control the processing of information through the node. According to one embodiment, illustrated in FIG. 3, the present invention provides a protection scheme for a network in the event that a “foreign” SMC is placed in the node. A foreign card comprises a SMC card containing invalid configuration files for the node wherein the card resides, while a “native” card is a card that has been acknowledged by an operator as belonging to the node or system wherein the card resides. The chassis ID code 31 stored in the configuration file of a native card matches the chassis ID code 33 of the node. For a foreign card, there is a discrepancy between the chassis ID code stored in the configuration file and the chassis ID code programmed into the backplane of the node. A foreign card may be a card that has been removed from a first node and inserted into a second node. From the perspective of the second node, the card is foreign, because the card has previously booted up in a different node and contains configuration information that is applicable to the other node. Alternatively, a foreign card can comprise a new card with a wiped hard disk (i.e. one where the contents have been reformatted or erased). When a foreign card is inserted into a new node from a first chassis, the foreign card contains configuration information for the first node. The insertion of a foreign card into an incorrect chassis results in a duplication of configuration information in the network in two nodes, the first node for which the card is configured and the node wherein the card is inserted. The configuration information contained in the foreign card corresponds to the first node, rather than the node in which it resides. This duplication and error in the node tends to confuse the network, preventing the efficient and accurate routing of traffic and leading to a potential network meltdown.

According to the illustrative embodiment of the present invention, when an SMC boots up in a node, the SMC initially performs a consistency check to ensure that the SMC resides in the correct chassis. The SMC first retrieves the chassis ID code from the backplane of the node in step 40 of FIG. 3. In step 41, the SMC validates itself by comparing the chassis ID code 33 from the backplane to the chassis ID code 31 in the configuration file 30 on the SMC. The chassis ID code 31 comprises the local chassis serial number for the node matching or corresponding to the SMC. If the SMC card is a native card containing valid configuration information for the node, then the actual chassis serial number (the chassis ID code 33) programmed into the backplane of the node matches the chassis serial number stored in the configuration file in the SMC. If the consistency check reveals a successful validation, indicating that the SMC is a native card and has previously booted up in the current system, the SMC initializes the non-volatile configurations stored in the configuration file in step 42. The SMC proceeds to synchronize the software and configuration files for the node with the backup SMC in step 43. In this manner, the backup SMC is prepared to replace the primary SMC if a failure of the primary SMC occurs. The SMC then allows all TCP connections to proceed to the daemons of the node, such as the trunk manager, port manager, signaling daemons in step 44. A “daemon” refers to a small process that runs within a multiprocessing system and performs a utility function at specified times, or in response to certain events. The node daemons, including the signaling daemon and the trunk manager daemon, are software components which create volatile configurations regarding the circuits, trunks, ports, IP addresses, and tunnels in the SMC memory. The node then processes and routes information signals through the network under the control of the SMC.

If the consistency check performed by the SMC reveals a mismatch between the contents of the configuration file 30 and the chassis ID code 33 (i.e. that the SMC is a foreign card), the illustrative embodiment of the invention further provides a procedure for protecting the existing hardware configuration of a system and containing the mismatch problem within the node. A mismatch prompts the node to flag the residing SMC as containing invalid configuration information for the node. Upon detection of a mismatch, the SMC first notifies a network user of the mismatch in step 45. For example, an alarm generator in the SMC raises an alarm, “Unapproved SMC with Chassis Serial # in <chassis> <slot>”. The SMC identifies the mismatched chassis identification code stored in the SMC, as well as the location of the mismatched SMC. In step 46, the SMC proceeds to disconnect sockets connections to the daemons, preventing the configuration file information from being downloaded and initializing the daemons with invalid configurations. In this manner, the SMC prevents the loss of circuits and trunks in the mismatched node. The SMC also inhibits the invalid IP address stored in the configuration file from propagating through the network in step 47 of the illustrative embodiment. As the IP address configured in a foreign SMC is in reality the IP address for a different node, the described safeguard prevents duplicate IP addresses from propagating through the network, which could lead to network confusion, meltdown, and incorrect routing of information. Upon detection of a mismatch, the SMC disables synchronization with the standby SMC in step 48, to avoid spreading bad or invalid configurations to the standby SMC as well.

The illustrative embodiment further provides a network management command to allow the user to clear the alarm generated by the SMC and validate the SMC as a native SMC for the node in step 49. The user approves a new or foreign SMC having a mismatched chassis ID code but correct configuration information. Upon receipt of the network management command from the user, the system first creates or updates the contents of the configuration file on the SMC to match the serial number stored in the backplane of the node. Then, the system clears the alarm generated in step 45, and sets the configuration file to a valid state.

During a mismatch, the node falls back to a default version of the node software and configuration (step 50) until the user has cleared the configuration mismatch problem. According to the present invention, the node includes memory for storing a default version of the node software and configuration information to be used in case of a mismatch. In this manner, the existing flow of information signals is maintained through the node without interruption.

According to one embodiment of the present invention, if the chassis ID code is missing from the configuration file during bootup of the system, the system considers the SMC to be foreign. Under these circumstances, the node of the present invention requires user intervention to set up and initialize the chassis ID code in the configuration file and restart the SMC. According to another embodiment, the standby SMC performs the described foreign card detection process every time the standby SMC assumes control of the switch. In this manner, the system of the present invention provides additional safeguards to prevent network meltdown due to a configuration mismatch.

FIG. 4 illustrates a recovery process for an alternate mismatch scenario according to the teachings of the present invention. When a chassis ID code 31 in the configuration file matches correctly with the chassis ID code 33 in the backplane and the daemons of the node start up, a discrepancy between the hardware configuration stored in the line cards of the node and the configuration information stored in the SMC may still exist. For example, in an optical switch, the configuration file on the SMC may contain more or less circuits than what the signaling daemon has configured in the actual hardware. To prevent data loss and maintain traffic flow, the existing circuits and trunks that are configured in the hardware must be maintained. FIG. 4 comprises a flow chart representing a set of consistency checks taken by the SMC to maintain the configuration of a node in the occurrence of a mismatch. While FIG. 4 illustrates actions taken by three particular daemons in an optical switch, a port manager, a trunk manager and a signaling daemon, the illustrative embodiment is not to be construed in a limiting sense. The described invention is applicable to any process that runs in a communications network.

In step 60 of FIG. 4, the SMC boots up with a correct configuration file, indicating that the primary SMC is a match for the node. To further validate the SMC, the following steps are taken. In step 61, the SMC reads the configuration information in the configuration file of the SMC to validate the configuration information. In step 62, the port manager validates the port configuration stored in the configuration file against the port information in the line cards of the node. According to a preferred embodiment, the port manager focuses on the verification of trunk versus user ports. If the validation fails, SMC raises an alarm notifying the user that the port configuration information is mismatched, in step 63. For example, the configuration file on the SMC recognizes a given port to be a trunk port, while the line card indicates that the port constitutes a user port, the SMC raises an alarm. In this scenario, the node utilizes the hardware configuration in the line cards during subsequent recovery procedures in order to maintain traffic flow.

Next, in step 64, the trunk manager confirms that it has the same number of trunks stored in the line cards as in a configuration file. This step ensures that the proper communication channels are established with neighboring nodes in the network. If the trunk validation fails, the SMC raises an alarm for mismatched trunks (step 65). Trunks that exist in hardware but not in the configuration file are flagged via alarms. Trunks in the configuration file stored in the SMC but not configured in the hardware are added to the hardware configuration of the node. For example, if the SMC indicates that there are three trunks for the node, while the line cards include only two trunks, the node adds an additional trunk to provide the necessary communications channel with three peer nodes in the network. The trunk manager initiates the additional configuration information to the hardware modules by downloading any new or additional trunks that need to be configured to the line cards in the node.

In step 66, the signaling daemon reads the hardware cross connects from a cross connect manager and validates the hardware cross connect information against the configuration file cross connect information. If the cross connect validation fails, the SMC generates an alarm to the user that the circuits are mismatched in step 67. Circuits that exist in hardware but not in the configuration file are flagged, while circuits in the configuration file but not in the hardware are consider new circuit creations and are added to the hardware configuration of the node. The signaling software initiates cross-connect connections to the hardware via the cross-connect manager software module.

Throughout the validation process, the SMC detects any configuration inconsistencies, raises an alarm to identify the inconsistencies, and continues operation without disrupting data flow. According to one embodiment, default software is stored on a disk on the node and the node reverts back to the default software and configuration files in case of a configuration mismatch. Thus, the node is still operational with a default configuration.

According to the illustrative embodiment of the present invention, the line cards provide configuration information to the SMC to recover and update a mismatched configuration file. Alternately, or in addition to the configuration information received from the line cards, the SMC can recover information through ftp or downloading of the configuration file from a database containing configuration files for the network. The database is periodically updated to maintain suitable configuration information for each node in the network. In addition, network elements may be further configured to synchronize configuration information with other network elements. During a mismatch of configuration information, a node may communicate with neighboring nodes to receive and update configuration information.

The illustrative embodiment of the present invention provides significant advantages to a communications network implementing the described protection scheme. According to the present invention, a node in a network avoids changes in existing hardware configurations and maintains a traffic flow despite a mismatch of configuration information. A significant feature of the invention is that the network protects a node from an unknown or foreign SMC with invalid configurations. The existing configuration, particularly the configuration of the cross-connects, remains intact during recovery procedure to prevent interruption of traffic flow. Through consistency checks, the SMC ensures that the correct control card for a node is placed in the node chassis. Furthermore, the SMC undergoes a number of steps to warn the user of a configuration problem and contain the problem to the node wherein the mismatched SMC resides.

The present invention has been described by way of example, and modifications and variations of the exemplary embodiments will suggest themselves to skilled artisans in this field without departing from the spirit of the invention. For example, the present invention is not limited to the use of daemons, as described. The node of the present invention can run any suitable processes, threads and the like for performing specified operations. Furthermore, the switch management card can comprise any suitable entity that is responsible for monitoring and maintaining configuration information. Features and characteristics of the above-described embodiments may be used in combination. The preferred embodiments are merely illustrative and should not be considered restrictive in any way. The scope of the invention is to be measured by the appended claims, rather than the preceding description, and all variations and equivalents that fall within the range of the claims are intended to be embraced therein.

Having described the invention, what is claimed as new and protected by Letters Patent is:

What is claimed is:

1. A node in a communications network, comprising:
an identification code;
a control mechanism including configuration information for the node; and
an alarm generator in the control mechanism for raising an alarm to a network user if there is a mismatch between the identification code and the configuration information.

2. The node of claim 1, wherein the identification code is programmed into the backplane of the node.

3. The node of claim 1, further comprising a network protocol based connection, wherein the control mechanism disconnects said connection during the mismatch between the identification code and the configuration information to prevent the configuration information from being downloaded to the node.

4. The node according to claim 1, wherein the node permits live communications traffic to continue uninterrupted through the node during the mismatch.

5. The node according to claim 1, further comprising at least one line card containing hardware elements, wherein said control mechanism is separated from the line card.

6. The node of claim 1, wherein the identification code comprises a chassis serial number.

7. The node of claim 1, wherein the control mechanism is a primary switch management card.

8. The node of claim 7, further comprising a standby switch management card that assumes responsibilities of the primary switch management card in the event of a failure of the primary switch management card.

9. The node of claim 8, wherein the mismatch prevents synchronization of the standby switch management card with the primary switch management card.

10. The node of claim 1, wherein said control mechanism runs a plurality of processes, wherein said processes perform a consistency check between stored configuration information and a hardware configuration for the node.

11. The node of claim 1, further comprising memory for saving a set of default configurations, wherein said node utilizes said set of default configurations when there is a mismatch between the identification code and the configuration information.

12. The node of claim 3, wherein the node disallows trunks from being configured during the mismatch.

13. The node of claim 3, wherein the node disallows circuits from being configured during the mismatch.

14. The node of claim 3, wherein the node prevents improper IP addresses from propagating through the network during the mismatch.

15. A method for restoring configuration information in a node of a communications network, comprising:
performing a consistency check between an identification code programmed into the node and configuration information stored in a control mechanism in the node; and
raising an alarm if the consistency check reveals a mismatch between the identification code and the configuration information.

16. The method of claim 15, wherein configuration information is prevented from being downloaded to the node while live communications traffic continues to be processed uninterrupted through the node.

17. The method of claim 15, further comprising a step of preventing invalid IP addresses from propagating through network if there is a mismatch.

18. The method of claim 15, further comprising a step of preventing a set of processes for the node from running if there is a mismatch.

19. A method of preserving configuration information in a node of a communications network when there is a discrepancy between a hardware configuration and configuration information stored in a control mechanism for the node, comprising:
performing a consistency check between the configuration information stored in the control mechanism and the hardware configuration of the node and in the vicinity of the node; and
raising an alarm if said consistency check fails to validate said configuration information against the hardware configuration.

20. The method of claim 19, further comprising a step of identifying inconsistencies between the configuration information and the hardware configuration.

21. The method of claim 19, wherein a port manager raises an alarm if a port configuration is mismatched.

22. The method of claim 19, wherein a trunk manager raises an alarm if a trunk configuration is mismatched.

23. The method of claim 19, wherein a signaling daemon raises an alarm if a cross connect is mismatched.

24. The method of claim 19, further comprising a step of recreating the configuration information in the control mechanism to match the hardware configuration.

25. The method of claim 24, wherein the step of recreating the configuration information in the control mechanism comprises synchronizing the configuration information in the control mechanism with configuration information registered in the hardware of the node.

26. The method of claim 25, wherein the step of recreating the configuration information in the control mechanism further comprises synchronizing the configuration information in the control mechanism with one or more neighboring nodes in the network.
